(19) United States
(12) Patent Application Publication
(10) Pub. No.: US 2005/0042881 A1
(43) Pub. Date: Feb. 24, 2005

(54) Processing apparatus

(75) Inventors: Shinya Nishimoto, Nirasaki-shi (JP); Masakazu Higuma, Nirasaki-shi (JP); Shinji Muto, Nirasaki-shi (JP); Hisashi Fujiwara, Nirasaki-shi (JP); Hiroyuki Nakayama, Nirasaki-shi (JP); Yoshinori Shimanuki, Nakakoma-gun (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/843,295

(22) Filed: May 12, 2004

(30) Foreign Application Priority Data
May 12, 2003 (JP) 2003-133531
Jun. 11, 2003 (JP) 2003-166822
Jun. 18, 2003 (JP) 2003-173787

(51) Int. Cl. H01L 21/68

(52) U.S. Cl. 438/710; 361/234

(57) ABSTRACT

The time period during which a wafer is stabilized to a predetermined temperature by increasing a thermal conductivity of a junction layer for bonding an electrostatic chuck layer and a support together, and the deterioration of the junction layer that is caused by active species generated by plasma is suppressed. Between the electrostatic chuck layer formed by sintering together a chuck electrode made of tungsten and an insulating layer made of alumina and the support, made of aluminum, for supporting the electrostatic chuck layer, the junction layer is provided to bond the electrostatic chuck layer and the support together. The junction layer is formed by impregnating a porous ceramic with a silicone-based adhesive resin. Further, rubber or a heat shrink tube made of a fluoric resin such as PFA is provided as a soft coating member so as to coat a side circumferential surface of the junction layer and the side circumferential surfaces of the electrostatic chuck layer and the support come into a tight contact with the heat shrink tube or rubber.

### TECHNICAL FIELD

The present invention relates to an apparatus for performing a vacuum processing on, for example, a substrate while adsorbing and holding the substrate by using an electrostatic chuck.

### PRIOR ART

Of semiconductor device manufacturing processes, there is a plurality of processes for performing on substrates in a vacuum environment, such as an etching process or a coating process using Chemical Vapor Deposition (CVD). A vacuum processing apparatus for performing such processes, for example, as shown in FIG. 17, is configured in such a way that a susceptor 91 for supporting a semiconductor wafer (hereinafter referred to as a “wafer”) W as well as functioning as a lower electrode is placed in a processing vessel 9, and a gas supply chamber 92 forming an upper electrode is placed above the susceptor 91. In the vacuum processing apparatus, a high frequency power is applied from a high frequency power source 91a to the susceptor 91, so that plasma is generated between the susceptor 91 and the gas supply table 92. As a result, a process gas introduced from the gas supply table 92 to the processing vessel 9 is activated and a predetermined processing is performed on the wafer W mounted on the susceptor 91 by using the activated process gas.

Meanwhile, the susceptor 91 is constructed in such a way that an electrostatic chuck layer 94 is placed on a support 93 and a conductive ring body 95 is installed to surround the electrostatic chuck layer 94. The electrostatic chuck layer 94 is formed by embedding a sheet-shaped chuck electrode 94a made of, e.g., tungsten into an insulating layer 94b made of dielectric, such as alumina. The electrostatic chuck layer 94 is supplied with a direct voltage from a power source (not shown) and adsorbs and holds the wafer W by using a Coulomb force generated by the supply of the direct voltage. Furthermore, reference numeral 96 shown in FIG. 17 refers to an exhaust pipe.

The electrostatic chuck layer 94 is formed by sequentially and thermally spraying alumina, which forms the lower insulating layer 94b, tungsten, which forms the chuck electrode 94a, and alumina, which forms the upper insulating layer 94b, on the upper surface of the support 93.

The electrostatic chuck layer 94 formed as described above has a strong residual adsorptive force exerted even after the application of the direct current voltage to the chuck electrode 94a is stopped. Furthermore, a thermally sprayed surface is uneven, which eventually causes a film separation on the surface to thereby produce particles that will be attached to the back surface of the wafer. There is a case where, in order to remove deposits attached to the inside of the processing vessel 9 near the susceptor 91 after a plasma processing has been performed, without mounting anything on the upper surface of the electrostatic chuck layer 94, oxygen gas is introduced into the processing vessel 9 and cleaning is performed by using the plasma of the oxygen gas. However, the case is problematic in that the surface of the electrostatic chuck layer 94 is damaged by the plasma of the oxygen gas.

From the above-described point of view, it has been considered to use a sintered plate as the electrostatic chuck layer and a detailed structure thereof is described in patent document 1. A susceptor using a sintered type electrostatic chuck layer, for example, as shown in FIG. 18, is constructed in such a way that a sintered plate 97, which is formed by coating an electrode 97a made of, e.g., tungsten with an insulating layer 97b, is bonded to support 93 made of, e.g., an aluminum through a junction layer 98 made of a silicone-based adhesive resin.

In the above-described susceptor 91, a coolant path (not shown) is formed in the support 93, and the surface of the support 93 is controlled to be kept at a predetermined reference temperature by passing temperature controlled coolant through the coolant path. Furthermore, the temperature of a wafer is adjusted to a predetermined temperature by dissipating heat from the wafer, which has been heated to a high temperature due to a plasma, to the support 93.

However, since the junction layer 98 is placed between the electrostatic chuck layer 97 and the support 93 and the silicone-based adhesive resin making up the junction layer 98 has a low thermal conductivity, it is difficult to transfer heat from the wafer W to the support 93, so that the equilibrium temperature is high and it takes a long time to stabilize the temperature of the wafer W at a predetermined desired process temperature. If it takes a long time to adjust the temperature of the wafer W, the desired processing cannot be performed immediately after startup, resulting in a reduction in throughput.

Although a focus ring 95 is placed around the side circumferential surface of the junction layer 98, there is a slight gap therebetween, so the side circumferential surface of the junction layer 98 is exposed to active species generated by the activation of process gas. Since the silicone-based adhesive resin making up the junction layer 98 has a low weatherproofness with respect to a fluoric radical, the side circumferential surface of the silicone-based adhesive resin is corroded by a fluoric radical in a process of creating a fluoric radical, for example, an etching process using process gas including fluorine. Since the thermal conductivity of the side circumferential surface of the corroded adhesive resin is low, it is difficult for heat transferred to the wafer to be dissipated from the side circumferential surface of the adhesive resin. Accordingly, as the junction layer 98 is corroded, the temperature of the circumferential portion of the wafer W increases, and thus the uniformity of the processing, e.g., the intra-surface uniformity of etching speed, is deteriorated, so that there is a problem in that the early replacement of the electrostatic chuck layer 97 is required.

[Patent Document 1]

Japanese Patent Laid-Open Application No. 1995-335731 (claim 1, paragraphs 0080, 0081 and 0082)

### DISCLOSURE OF THE INVENTION

[Problems to be Solved by the Invention]

It is, therefore, an object of the present invention to provide a technology capable of shortening the time required for a wafer to be stabilized to a predetermined temperature by increasing the thermal conductivity of a junction layer that bonds an electrostatic chuck layer and a support together.

Another object of the present invention is to provide a technology capable of suppressing the deterioration of the junction layer that is caused by active species generated by plasma.

[Means to Solve Problems]

The present invention provides a processing apparatus including a processing vessel for performing a predetermined processing on a substrate; an electrostatic chuck layer for holding the substrate by using an electrostatic adsorption force generated by a voltage applied, the electrostatic chuck layer being placed in the processing vessel and formed by coating a chuck electrode with an insulating layer; a support for supporting the electrostatic chuck layer; and a junction layer for bonding the support and the electrostatic chuck layer together, the junction layer being interposed between the support and the electrostatic chuck layer and formed by impregnating a porous ceramic with an adhesive resin.

In the above-described construction, by using a highly thermally conductive porous ceramic impregnated with an adhesive resin as a junction layer, not only the adhesive force can be assured, but also the thermal conductivity of the junction layer can be increased, so that a substrate can be stabilized at a predetermined temperature. In this case, alumina, aluminum nitride or silicon carbide can be used as the porous ceramic. Furthermore, a silicone-based adhesive resin or an acrylic-based adhesive resin is used as the adhesive resin.

Additionally, the present invention provides a processing apparatus including a processing vessel for performing a plasma processing on a substrate; an electrostatic chuck layer for holding the substrate by using an electrostatic adsorption force exerted from a field generated due by a voltage applied, the electrostatic chuck layer being placed in the processing vessel and formed by coating a chuck electrode with an insulating layer; a support for supporting the electrostatic chuck layer; a junction layer for bonding the support and the electrostatic chuck layer together, the junction layer being interposed between the support and the electrostatic chuck layer and formed by impregnating a porous ceramic with an adhesive resin; and a protection layer for protecting the junction layer against active species generated by a plasma, the protection layer being formed around a side circumferential surface of the junction layer.

In the above-described construction, by placing a protection layer of a good weatherproofness to the active species on the side circumferential surface of the junction layer in the case of performing a plasma processing on a substrate in the processing vessel, not only the side circumferential surface of the junction layer is exposed to the active species, but also the deterioration of the junction layer by the active species can be suppressed.

The protection layer is formed by impregnating a protection layer solution, which is formed by dissolving protection layer components in a solvent, into the side circumferential surface of the junction to a predetermined depth, and eliminating the solvent from the protection layer solution through heating. Furthermore, a component of the protection layer is preferably an inorganic material that is not etched by the active species generated by the plasma.

The processing apparatus may perform a plasma processing on the substrate and the support may be provided with cooling means for controlling a temperature of the support at a predetermined temperature. The processing apparatus may further include a process gas supply unit for supplying a process gas into the processing vessel and a high frequency power supply for applying a plasma generation high frequency power to the support, wherein the plasma may be generated in the processing vessel and the process gas may be activated by the plasma. Furthermore, the electrostatic chuck layer may be formed of a sintered body that is formed by coating the chuck electrode with the insulating layer.

Additionally, the present invention provides a processing apparatus including a processing vessel for performing a plasma processing on a substrate; an electrostatic chuck layer for holding the substrate by using an electrostatic adsorption force exerted by the field generated by the voltage applied, the electrostatic chuck layer being placed in the processing vessel and formed by coating a chuck electrode with an insulating layer; a support for supporting the electrostatic chuck layer, the support being made of a material different from that of the electrostatic layer; a junction layer for bonding the support and the electrostatic chuck layer together, the junction layer being interposed between the support and the electrostatic chuck layer and formed by impregnating a porous ceramic with an adhesive resin; and a coating member for protecting the junction layer against active species generated by a plasma, the coating member being formed to coat a side circumferential surface of the junction layer.

The coating member is preferably a heat shrink tube. In this case, the heat shrink tube is preferably made of a fluoric resin. Examples of the fluoric resin include tetrafluoroethylene perfluoroalkoxy vinyl ether (PFA), tetrafluoroethylene-perfluorpropylen copolymer (FEP) and polytetrafluoroethylene (PTFE). Furthermore, the coating member may be rubber or elastomer. In the case of using a material other than the fluoric resin as the coating member, the surface of the material is preferably coated with fluorine.

In the case of using the coating member, a depression may be formed by projecting the electrostatic chuck layer and the support to an outside of the junction layer, and the coating member may be fitted into the depression so that the coating member pushes surfaces of the electrostatic chuck layer and the support with the help of a restoring force within the depression. Furthermore, a silicone-based adhesive resin or an acrylic-based adhesive resin may be used as the junction.

In the case of supplying a high frequency power to the support to generate a plasma, one or more spacers having a relative dielectric constant equal to that of the junction layer may be interposed between the electrostatic chuck layer and the support. In this case, the spacer is formed of a ceramic piece, and the junction layer is formed by mixing the adhesive resin with ceramic powder that is a filler material. Furthermore, the junction layer is made of one of the silicone-based adhesive resin and the acrylic-based adhesive resin. In this case, the equivalence imports that, if it is assumed that the relative dielectric constant of the spacers 171 is ε1 and the relative dielectric constant of the junction layer 172 is ±2, then they satisfy a relationship given as 0.90ε2≦ε1≦1.10ε2. As described above, when the relative dielectric constants of the spacers and the junction layer are made equivalent, an impedance with respect to the high frequency voltage becomes uniform in a plane direction. Accordingly, since the efficiency of the high frequency power becomes uniform in a plane direction, a plasma processing of high intra-surface uniformity can be performed.

In accordance with the present invention, the electrostatic layer and the support are bonded together by placing the junction layer, which is formed by impregnating the porous ceramic with the adhesive resin, between the electrostatic layer and the support such that the thermal conductivity of the junction layer is increased and the time required for the substrate to be stabilized at a predetermined temperature is shortened. By selecting an adhesive resin of a high adhesive force while at the same time assuring a high thermal conductivity by using the porous ceramic, a junction layer whose thermal conductivity and adhesive force are both excellent can be obtained. Furthermore, the protection layer is formed on the side circumferential surface of the junction layer, so that the deterioration of the junction layer by the active species generated by the plasma can be suppressed.

Furthermore, in accordance with the present invention, a soft coating member is provided to coat the side circumferential surface of the junction layer, so that the deterioration of the junction layer by the active species generated by the plasma can be suppressed. Furthermore, since the coating member is a soft material, even if the electrostatic chuck layer and the support are thermally expanded by heating, the thermal expansion can be accommodated, so that tight contact can be maintained because there will be no brittle breakdown and no gap will be opened.

### BEST MODES FOR CARRYING OUT THE INVENTION

(First Embodiment)

A first embodiment of a processing apparatus in accordance with the present invention is described with reference to FIGS. 1 and 2. FIG. 1 is a longitudinal section showing an entire construction of an example of an etching apparatus that is a processing apparatus of the present embodiment. In this drawing, reference numeral 1 designates a vacuum chamber making up a processing vessel, and is made of, e.g., aluminum to form an airtight structure. In the vacuum chamber 1, an upper electrode 11, also functioning as a gas showerhead (process gas supply unit), and a susceptor 2, also functioning as a lower electrode, are mounted opposite to face each other, and a gas exhaust port 10 is formed in the bottom of the vacuum chamber 1 to communicate with a vacuum pump (not shown). Openings 12 and 13 are formed in the sidewalls of the vacuum chamber 1 to carry in and out a semiconductor substrate, for example, a wafer W, and can be selectively opened and closed by gate valves G, respectively. Permanent magnets 14 and 15 having, for example, ring shapes, are placed above and below respective openings 12 and 13 outside the sidewalls of the vacuum chamber 1.

A plurality of holes 16 is formed through the bottom surface of the upper electrode 11, and a gas supply line 17 extending from a gas supply source (not shown) is connected to the upper surface of the upper electrode 11. The process gas supplied through the gas supply line 17 is spread through a process gas path 18 formed in the upper electrode 11, passes through the holes 16, and is directed toward the surface of the wafer W mounted on the upper surface of the susceptor 2. Furthermore, the upper electrode 11 is grounded.

Next, the susceptor 2 forming a major part of the present embodiment is described in detail. The susceptor 2 is formed of, e.g., a circular shape, and has an electrostatic chuck layer 3 on the upper surface of a support 21 of a conductive, for example, metallic, support. The support 21 (susceptor body) is formed of, for example, aluminum. A coolant path 22 is formed through the support 21, and the surface of the support 21 is adjusted to a predetermined reference temperature, for example, about 10˜60° C., by passing coolant, which has been controlled at a predetermined temperature by a temperature control unit 23, through the coolant path 22 via a coolant supply unit 24. The coolant path 22, the coolant supply means 24, and the temperature control unit 23 correspond to cooling means of the present invention.

The electrostatic chuck layer 3 is formed by sintering together a chuck electrode 31 made of, for example, tungsten of a sheet shape and an insulating layer 32 made of an insulating material, such as alumina, wherein the chuck electrode 31 is placed within the insulating layer 32. The chuck electrode 31 is formed of a plate having a thickness of, e.g., about 1 mm to 2 mm and is connected to a direct current power source 33 through a resistor R1. The susceptor 2 includes the electrostatic chuck layer 3, and the wafer W is adsorbed and maintained on the surface (upper surface) of the insulating layer 32.

The electrostatic chuck layer 3 formed of sintered materials is formed by preparing an upper and a lower layer part that are formed by mixing and pressure-firing alumina particles and binders, coating a mixture of tungsten particles and binders on the upper surface of the lower layer part, placing the upper layer part on the lower layer part coated with the mixture, and further pressure-firing the upper and the lower layer part.

A junction layer 4 is formed between the support 21 and the electrostatic chuck layer 3 to bond together the support 21 and the electrostatic chuck layer 3. The junction layer 4 is formed of a plate-shaped body about 0.3˜0.8 mm thick formed by impregnating a porous ceramic 41 having a high thermal conductivity with an adhesive resin, and is placed with the upper and the lower surface thereof to come into contact with the lower surface of the electrostatic chuck layer 3 and the upper surface of the support 21, respectively. The porous ceramic 41 is made of a material having a thermal conductivity of, e.g., about 0.02˜280 W/m·K, for example, aluminum nitrite AlN, silicon carbide SiC or alumina Al₂O₃.

An example of a method of producing such porous ceramic is described below. A raw material powder is combined with a sintering additive or impurities, and the resulting combination is formed by a Cold Isostatic Press (CIP) method. After the resulting formed body is fired under a pressure while the pressure is maintained constant or increased, machining such as surface grinding and washing are performed on the resulting body, thereby manufacturing the porous ceramic. In this case, a silicone-based adhesive resin or an acrylic adhesive resin having a thermal conductivity of about 0.2˜2.0 W/m·K may be used as the adhesive resin.

The junction layer 4 is formed by impregnating the porous ceramic 41, which is formed by the above-described method, with the adhesive resin, and an example of the method of producing the junction layer 4 is described with reference to FIG. 3. FIG. 3A shows a state of the porous ceramic 41. The adhesive resin is coated on the surface of the porous ceramic 41 (see FIG. 3B). When the adhesive resin is coated on the porous ceramic 41, the adhesive resin infiltrates through holes 42 in the vicinity of the surface of the porous ceramic 41 and then gradually infiltrates deeper into the interior of the porous ceramic 41. As a result, the holes 42 of the porous ceramic 41 are filled with the adhesive resin, and in this present invention, the state where the holes 42 of the porous ceramic 41 are filled with the adhesive resin is referred to as the state where the porous ceramic is impregnated with the adhesive resin (see FIG. 3C). In this forming method, a thermoplastic resin is used as the adhesive resin.

After the porous ceramic 41 has been impregnated with the adhesive resin as described above, a protection layer 5 is formed around the side circumferential surface of the junction layer 4. The protection layer 5 (not shown in FIG. 1 for ease of illustration) is formed to prevent the deterioration of the junction layer 4 due to radicals by preventing the side circumferential surface of the junction layer 4 from coming into contact with active species (radicals) generated by the plasma of process gas. For this purpose, the protection layer 5 is formed of a material that is not etched by radicals, for example, an inorganic material, such as silica. As shown in FIG. 3E, the side circumferential surface of the junction layer 4 is coated with a protection layer solution such that a region 43 ranging over approximately 1 mm deep inside the junction layer 4 from the side circumferential surface of the junction layer 4 is impregnated with the protection layer solution in which the components of the protection layer 5 are dissolved in a solvent as shown in FIG. 3D.

The protection layer solution is solidified by heating the junction layer 4 to a temperature, for example, about 80° C., as shown in FIG. 3F. By this, the junction layer 4 is formed and the region impregnated with the protection layer solution is formed as the protection layer 5.

Since the junction layer 4 is formed by impregnating the highly conductive porous ceramic with the adhesive resin, the thermal conductivity of the entire junction layer 4 is approximately 20˜40 W/m·K even though the thermal conductivity of the adhesive resin is low.

Referring again to FIG. 1, a ring member 6 making up a conductive member is placed around the electrostatic chuck layer 3 on the susceptor 2. The ring member 6 functions to improve the uniformity in an etching rate on the surface of the wafer W by expanding a plasma, which is generated in the vacuum chamber 1, over an area larger than the wafer W, and is made of a conductive material, for example, silicon. An elevation member (not shown) for carrying in and out the wafer W is installed in the susceptor 2, and a high frequency power source 25 is connected to the susceptor 2, for example, to the support 21 thereof, through a condenser C1 and a coil L1 to apply a high frequency for the generation of the plasma.

An example of a method of producing the susceptor 2 is described with reference to FIGS. 4A to 4E. For example, as shown in FIG. 4A, the adhesive resin is coated on the support 21, and the porous ceramic 41 is placed on the support 21 coated with the adhesive resin. Thereafter, the junction layer 4 formed by impregnating the porous ceramic 41 with the adhesive resin is formed by coating the adhesive resin on the surface of the porous ceramic 41. Thereafter, as shown in FIG. 4B, the electrostatic chuck layer 3 formed of the sintered body produced by the above-described method is mounted on the junction layer 4. Subsequently, as shown in FIG. 4C, the protection layer solution is coated on the side circumferential surface of the junction layer 4 to form the protection layer 5. Thereafter, as shown in FIG. 4D, the adhesive resin of the junction layer 4 is softened by performing curing at, for example, 130° C. for a predetermined period, the adhesive resin is solidified and the protection layer 5 is formed at the same time by performing cooling, thus obtaining the susceptor 2 (see FIG. 4E). The junction layer may be formed separately, as shown in FIGS. 3A to 3F, or may be formed on the support 21, as shown in FIGS. 4A to 4E.

The operation of the present embodiment will now be described. When the gate valve G is opened, the wafer W is carried in through the opening 12 (13) and is mounted on the surface of the electrostatic chuck layer 3 within the vacuum chamber 1 by a transport arm. After the transport arm is retreated and the gate valve G is closed, the internal pressure of the vacuum chamber 1 is adjusted to remain in the range of 10⁻²˜10⁻³ Pa by exhausting gas from the vacuum chamber 1 through the gas exhaust port 10. At this time, a DC voltage is applied to the chuck electrode 31, so that the wafer W remains attached to the surface of the electrostatic chuck layer 3 by a Coulomb force.

Thereafter, the plasma is made to have a high density by supplying a process gas, for example, C₄F₈ gas, to the wafer W and applying a high frequency voltage from the high frequency power source 25 to the susceptor 2 which serves as the lower electrode at the same time. Thereby, the process gas is activated, and the etching of the surface of the wafer W, for example, a silicon oxide film, is performed.

In the case, since the wafer W is exposed to the plasma and heated to a high temperature while the surface of the support 21 is maintained at the reference temperature, for example, 60° C., heat is rapidly transferred from the wafer W through the electrostatic chuck layer 3 and the junction layer 4 to the support 21. Consequently, the temperature of the wafer W is controlled to be kept at a predetermined process temperature, for example, 100° C., based on the heating of the wafer W by the plasma and the reference temperature of the support 21. By this, the etching is completed, and then the wafer W is carried out of the vacuum chamber 1 in a reversed process order to that when it being carried in

In the above-described construction, the support 21 and the electrostatic layer 3 are bonded together by the junction layer 4 that is formed by impregnating the high conductive porous ceramic 41 with the adhesive resin, so that not only a high adhesive force can be assured, but also a thermal conductivity can be improved. That is, a silicone-based adhesive resin having a high adhesive force is preferably used as an adhesive to bond together the electrostatic chuck layer 3 and the support 21, but it has a low thermal conductivity. For this reason, the silicone-based adhesive resin is not used as it is. Instead, the silicone-based adhesive resin is impregnated into the porous ceramic 31, and the junction layer 4 is formed by the combination of the porous ceramic 31 and the adhesive resin, so that not only a high adhesive force but also a high thermal conductivity can be assured at the same time.

Accordingly, by using the above-described junction layer 4, the support 21 and the electrostatic chuck layer 3 are not only sufficiently bonded together by the silicone-based adhesive resin, but a rapid heat transfer is also realized between the support 21 and the electrostatic chuck layer 3 through the porous ceramic 41. As a result, since heat is rapidly transferred from the wafer W heated to a high temperature through the electrostatic chuck layer 3 and the junction layer 4 to the support 21, the reception and the transfer of heat are rapidly performed between the wafer W and the support 21, so that the temperature of the wafer W can be easily controlled and the wafer W heated to a high temperature is cooled and stabilized to a predetermined temperature in a short period. Since the temperature of the wafer W is stabilized in a short period after the initiation of the process, the process can start immediately, so that the total processing time can be shortened and an improvement in throughput can be obtained.

The above-described result is illustrated in FIG. 5. In FIG. 5, a solid line represents the relationship between wafer temperature and processing time in the case of using the junction layer 4 in accordance with the present invention, and a dotted line represents the relationship between wafer temperature and processing time in the case of using only the silicone-based adhesive resin. As described above, in the case of using the junction layer 4 in accordance with the present invention, the temperature of the wafer W is rapidly stabilized to the predetermined process temperature based on heating by the plasma and cooling by the support 21 through the junction layer 4. In contrast, in the case of using the silicone-based adhesive resin as the junction layer, the thermal conductivity of the silicone-based adhesive resin is low, so that it is difficult for heat to be transferred from the wafer W to the support 21. Accordingly, the processing time is prolonged, so that the temperature of the wafer W gradually increases and therefore becomes difficult to be stabilized to a predetermined temperature.

Since, in the above-described construction of the present invention, the thermal conductivity of the junction layer 4 is high, and the reception and the transfer of heat is rapid, so that it is easy for the wafer W to be cooled, and therefore the temperature difference between the wafer W and the support 21 can be decreased in a short period. With this, the reference temperature of the support 21 can be set to a temperature higher than a conventional reference temperature, so that the cooling capability of the cooling means of the support 21 can be set low. Accordingly, the load on the cooling system can be reduced, thereby making the temperature control easy.

In this case, the adhesive force and the thermal conductivity of the junction layer 4 are dependent on the degree of impregnation of the adhesive resin into the porous ceramic 41. In detail, when the degree of impregnation of the adhesive resin into the porous ceramic 41 is high, the adhesive force increases while the thermal conductivity decreases. In contrast, when the degree of impregnation of the adhesive resin into the porous ceramic 41 is low, the adhesive force decreases, but the thermal conductivity increases.

Meanwhile, the degree of impregnation of the adhesive resin into the porous ceramic 41 is dependent on the porosity of the porous ceramic 41. In detail, when the porosity of the porous ceramic 41 is high, the degree of impregnation increases. In contrast, when the porosity of the porous ceramic 41 is low, the degree of impregnation decreases. For this reason, to improve thermal conductivity while assuring a sufficient adhesive force, it is required to optimize the porosity of the porous ceramic 41.

Furthermore, since heat is transferred to the support 21 through the electrostatic chuck layer 3 and the junction layer 4, it is preferable to make the thermal conductivity of the electrostatic chuck layer 3 coincide with that of the junction layer 4 in order that the temperature of the wafer W can be easily controlled. Based on the fact that the thermal conductivity of the electrostatic chuck layer 3 formed of the above-described sintered body ranges from 20 W/mK to 40 W/m·K, it is preferable that the thermal conductivity of the junction layer 4 ranges from 20 W/m·K to 40 W/m·K.

Even though, in the above-described junction layer 4, the radicals of the components of the process gas generated by the plasma enter between the junction layer 4 and the ring body 6 and come into contact with the side circumferential surface of the junction layer 4, the side circumferential surface of the junction layer 4 is provided with the protection layer 5 having weatherproofness with respect to the radicals and is made of a material that is not etched by the radicals, so that the junction layer 4 itself is prevented from coming into contact with the radicals. For this reason, there will hardly occur any temporal changes in the thermal conductivity and the adhesive force of the junction layer 4. Accordingly, a stable processing can be performed over a long period, so that the life span of the susceptor 2 is long.

Experiments for ascertaining the effects of the present invention are described below. A disk-shaped aluminum nitride having a diameter of 300 mm, a thickness of 0.5 mm, an average hole size of 30 μm and a porosity of 50% was used as the porous ceramic 41, and the susceptor 2 was produced by the method illustrated by using FIG. 4. In this case, a sintered body, which was formed by coating a tungsten electrode with alumina and was of 1 mm thick, was used as the electrostatic chuck layer. A heating process had been performed at, for example, 130° C. for 15 minutes to solidify the adhesive resin or the protection layer 5.

The thermal conductivity of the junction layer 4 configured as described above was measured to be 22 W/m·K. Accordingly, the junction layer 4 in accordance with the present invention was recognized as guaranteeing thermal conductivity 10 times higher than that of the silicone-based adhesive resin that was 2.0 W/m·K.

Using the processing apparatus including the susceptor 2, the above-described etching processes had been performed for 3000 H and the thermal conductivity was measured for each of the processes. It can be appreciated that, since there was no change in the thermal conductivity of the junction layer 4, the deterioration of the junction layer 4 due to the radicals was suppressed, so that the life span of the susceptor 2 was prolonged.

In the present invention, the electrostatic chuck layer 3 is not limited to the one made of a sintered body, but may be formed by thermal spraying. In this case, after the junction layer 4 is mounted on the support 21, the electrostatic chuck layer 3 is thermally sprayed on the upper surface of the junction layer 4. Furthermore, the present invention can be applied to coating, ion implantation and ashing as well as etching.

(Second Embodiment)

Another embodiment of the present invention is described below. FIG. 6 is views showing a susceptor 7 used in the present embodiment. The other parts of the processing apparatus (etching apparatus) of the present invention are identical with those of FIG. 1. In FIGS. 2 and 6, the same numerals designate the same parts. A junction layer 70 is used to bond together an electrostatic chuck layer 3 and a support 21, and is made of, for example, a silicone-based adhesive. A soft coating member 71 is placed around the side circumferential surface of the junction layer 70 to protect the junction layer 70 against active species generated by the plasma, for example, fluoric radicals or fluoric ions. As shown in FIG. 6B that is a partially enlarged view of FIG. 6A, a thermally sprayed coating 72 is formed along the circumferential portion of the central portion of the upper surface of the support 21, that is, a protrusion bonded to the electrostatic chuck layer 3. The thermally sprayed coating 72 is formed as an insulating portion to prevent an abnormal discharge of a plasma.

A heat shrink tube made of, for example, a fluoric resin is used as the coating member 71. The fluoric resin includes tetrafluoroethylene perfluoroalkoxy vinyl ether (PFA), tetrafluoroethylene-perfluorpropylen copolymer (FEP) and polytetrafluoroethylene (PTFE). The advantages in using a fluoric resin are that the fluoric resin has a high heat-resistance, so that PFA can stand against temperature of 260° C. and FEP can stand against temperature of 200° C., has a low gas permeability, so that active species are not transmitted to the junction layer 70, and the fluoric resin is not easily consumed even though the surface of the fluoric resin reacts with active species. Furthermore, since the fluoric resin has a few contained impurities, the impurities are not scattered even though the fluoric resin is used for a long time and, therefore, the surface of the fluoric resin reacts with active species and is consumed. Furthermore, the heat shrink tube has characteristics in that it shrinks when heat is applied thereto and does not return to its original shape after it shrinks once. When the characteristics of the heat shrink tube used in the case where the susceptor 7 has a size suitable for mounting a 200 mm diameter wafer are taken as an example, the diameter of a 206 mm diameter heat shrink tube made FEP is reduced to 160 mm if the diameter heat shrink tube is heated to, for example, 150˜200° C. Furthermore, when a 211 mm diameter made of FPA is heated to, for example, 150˜200° C., the diameter of the heat shrink tube is reduced from 211 mm to 185 mm. Using these characteristics, the entire side circumferential surface of the susceptor 7 can be coated even though the circumference of the susceptor 7 does not form a perfect circle.

A method of fitting the heat shrink tube, that is, the coating member 71, around the side circumferential surface of the junction layer 70 is described in detail with reference to FIG. 7 below. As shown in FIG. 7A, a ring-shaped heat shrink tube having a diameter slightly larger than that of the electrostatic chuck layer 3 is placed on the support 21 to surround the side circumferential surface of the central protrusion of the support 21, on which the electrostatic chuck layer 3 is placed through the junction layer 70, and the side circumferential surface of the electrostatic chuck layer 3. Thereafter, when the susceptor 7 is put into a thermostatic tub and is heated to, for example, 130° C., the diameter of the heat shrink tube is reduced by heat and the heat shrink tube comes into tight contact with the side circumferential surface of the electrostatic chuck layer 3 and the side circumferential surface of the protrusion of the support 21 coated with the thermally sprayed coating 72 as shown in FIG. 7B. Even in the case where a D-cut 3a (rectilinear portion formed on a portion of the side circumferential surface of the electrostatic chuck layer 3) is formed on a portion of the susceptor 7 to correspond to the notch or orientation flat portion of a wafer, the heat shrink tube can coat all the side circumferential surfaces while being in tight contact with the side circumferential surfaces. Subsequently, the susceptor 7 is carried out of the thermostatic tub and put into the vacuum chamber 1. Furthermore, if a heater is attached to the susceptor 7 to heat the susceptor 7 and a reduction in the diameter of the heat shrink tube is preformed by the activation of the heater, it is not necessary to use the thermostatic tub.

In general, the heat shrink tube made of PFA or FEP rapidly shrinks when it is heated to 150˜200° C. However, even if it is heated to only 100˜150° C., it still can shrink. As for a general electrostatic chuck layer 3 having a heat-resistant temperature of about 150° C. and an alumite coating, the heat shrink tube can be fitted around the electrostatic chuck layer 3 without damaging the electrostatic chuck layer 3 by heat.

In order to prevent the side circumferential surface of the junction layer 70 from being exposed to the environment of the processing chamber, the coating member 71 constructed as described above makes a tight contact with the electrostatic chuck layer 3 and the support 21; the coating member 71 otherwise, may contact tightly with the side circumferential surface of the junction layer 70 or may have a gap from the side circumferential surface of the junction layer 70.

Furthermore, the heat shrink tube is not limited to the fluoric resin, but may be made of silicon rubber or polyolefin. In the case where a material other than the fluoric resin is used as the material of the heat shrink tube, the surface of the heat shrink tube is preferably coated with fluorine to prevent the deterioration of the material of the heat shrink tube, for example, the deterioration of the resin, caused by active species.

An example of a method of coating a base material with fluorine is described. The surface of the base material (in this case, the heat shrink tube) is made coarse by blasting; a primer is coated on the surface of the base material; and the base material coated with the primer is baked by heating the base material in a heating furnace. In this case, a desired fluoric coating may be formed on the surface of the base material by repeating the last step a plurality of times.

The fluoric coating layer may be directly formed on the side circumferential surfaces of the support 21, the junction layer 70 and the electrostatic chuck layer 3 by coating a fluoric coating material on the side circumferential surfaces thereof and heating and firing the support 21, the junction layer 70 and the electrostatic chuck layer 3 in a heat furnace.

The present embodiment has the following effects. As described in conjunction with the first embodiment, a process gas, such as C₄F₈ gas, NF₃ gas or SF₆ gas, becomes a plasma during an etching process, and active species including fluoric radicals are produced. At this time, an active species group enters into the gap between the wafer W and the ring member 6, but is prevented from coming into contact with the side circumferential surface of the junction layer 70 because the coating member 71 is fitted while shrinking, that is, the coating member 71 contacts tightly with the electrostatic chuck layer 3 and the support 21 under the shrinking force. Since, for this reason, the adhesive used as the junction layer 70 is not corroded, the thermal conductivity of the junction layer 70 does not change and there is hardly any occurrence of a temporal increase in the temperature of the outer circumferential portion of a wafer, a stable processing can be performed over a long period, and thus the life span of the susceptor 7 is prolonged. In particular, in the processing using NF₃ gas or SF₆ gas, the concentration of fluoric radicals increases, so that the junction layer is extremely corroded and the life span of the susceptor 7 is extremely shortened if the junction layer 70 is made of a silicone rubber-based adhesive as in the conventional configuration. In contrast, in the present embodiment, the life span of the susceptor 7 can considerably increase.

Furthermore, during an etching process, the electrostatic chuck layer 3 and the support 21 are heated and expanded by the heat from the plasma. In general, the ceramic plate used as the electrostatic chuck layer 3 has a low linear expansion coefficient compared to that of a metallic base material. Accordingly, if a coating member is made of a hard material, the coating member cannot accommodate the thermal expansion of the electrostatic chuck layer 3 and the support 21 and therefore becomes fractured or separated due to a gap being opened therebetween. In contrast with the coating member made of a hard material, the coating material 71 in accordance with the present embodiment is soft, so that the coating material 71 can accommodate the thermal expansion of the electrostatic chuck layer 3 and the support 21, thus remaining in tight contact therewith without brittle breakdown or separation.

The coating member 71 is not limited to a heat shrink tube, but may be made of an elastic body such as rubber or elastomer. When an elastic ring, while expanded, is fitted around the side circumferential surfaces of the protrusion of the support 21 and the electrostatic chuck layer 3, the elastic ring contacts tightly with the side circumferential surfaces due to a restoring force exerted on the side circumferential surfaces, thus exhibiting the same effects described above. In this case, the above-described fluoric coating processing is preferably performed on the elastic body. Furthermore, instead of the fluoric coating, Diamond-Like Carbon (DLC) coating may be applied. When a material stabilized by fluorinating the end of the heat shrink tube made of PFA is used, the use of the material is desirable because it is difficult for fluoric ions to be produced while the material reacts with active species.

Another example of the contact structure of the coating member 71 is briefly described with reference to FIGS. 8A and 8B. FIG. 8A shows the structure, in which the peripheral portion of the electrostatic chuck layer 3 is projected to the outside of the junction layer 70, the bottom surface of the projected portion is inclined to be gradually lowered inwardly, and a coating member 71 having an elastomer ring body called an O-ring is fitted into a space 73 that is defined by the inclined surface of the electrostatic chuck layer 3, the upper surface of the portion of the support 21 extended to the outside of the junction layer 70, and the junction layer 70. With the above-described structure, the coating member 71 shrinks inwardly along the inclined surface of the electrostatic chuck layer 3 and is brought into tight contact with contact surfaces around the space 73 due to the restoring force of the coating member 71, so that the great contact force can be achieved between the electrostatic chuck layer 3 and the support 21 and the coating member 71. FIG. 8B shows the structure, in which an elastomer coating member 71 having a rectangular section is fitted into a rectangular groove 74 that is defined by the bottom surface of the peripheral, a projected portion of the electrostatic chuck layer 3 and the support 21, so as to protect the junction layer 70.

The junction layer 70 employed in the second embodiment may be made of a silicone-based adhesive resin or an acrylic-based adhesive resin. Alternatively, the junction layer 70 may be made of some other adhesive resins.

When the heat shrink tube was brought into tight contact with the surface (the surfaces of the electrostatic chuck layer and the support) of a susceptor for mounting a wafer having an orientation flat, that is, the susceptor formed in a similar shape to the wafer having the mounting flat, it was found out that there was no gap opened between the surface of the susceptor (including the portion of the orientation flat) and the heat shrink tube, so that the heat shrink tube evenly contacted tightly with the surface of the susceptor.

(Third Embodiment)

A third embodiment of the present invention is described below. FIG. 9 is a longitudinal section showing an entire structure of an etching apparatus with a plasma apparatus, which is a processing apparatus related to the practice of the invention, applied thereto. In FIG. 9, reference numeral 120 designates a processing vessel that is made of a conductive material, such as aluminum, and is air-tightly sealed. The processing vessel 120 is grounded. In the processing vessel 120, an upper electrode 130, which also functions as a gas shower head that is a gas supply unit for introducing a process gas, and a susceptor 140, which is used to mount a wafer W and also functions as a lower electrode, are placed opposite to face each other. A gas exhaust pipe 121 is connected to the bottom of the processing vessel 120, and vacuum exhaust means, such as a turbo molecular pump or dry pump, is connected to the gas exhaust pipe 121. An opening 123, which is provided with a selectively openable gate valve 123a and is used to carry in and out a wafer W, is formed through the sidewall of the processing vessel 120.

A plurality of gas diffusion holes 132 is formed through the bottom surface of the upper electrode 130 to communicate with a gas supply line 131, and is configured to supply a process gas toward the wafer W mounted on the susceptor 140. Furthermore, the gas supply line 131 is connected to a gas supply source 131b through a flow rate control unit 131a. The upper electrode 130 is connected through a low pass filter 133 to a high frequency power supply unit 134 for supplying a high frequency power having a frequency of, for example, 60 MHz. A shield ring 135 made of an annular quartz is fitted around the circumferential portion of the upper electrode 130.

The susceptor 140 includes a column-shaped support (susceptor body) 150 made of conductive material such as aluminum, and an electrostatic chuck layer 160 is seated on the surface of the support 150. The electrostatic chuck layer 160, as shown in FIG. 10, is formed by embedding a sheet-shaped chuck electrode 162 in a ceramic plate 161 that is a dielectric plate made of a dielectric, such as ceramic Al₂O₃. The ceramic plate 161 is of, for example, 1˜5 mm in thickness. The ceramic used in the present embodiment includes aluminum nitride AlN, yttrium oxide Y₂O₃, lead nitride PbN, silicon carbide SiC, titan nitrite TiN or magnesium oxide MgO. A plurality of spacers 171 is interposed between the top surface of the support 150 and the bottom surface of the electrostatic chuck layer 160, and a junction layer 172 is formed therebetween. Each of the spacers 171 is a circularly shaped ceramic piece that is of, for example, 0.01˜0.1 mm in thickness and 1˜5 mm in diameter. For example, as shown in FIG. 11, one spacer 171 is placed at the center of the upper surface of the support 150, and the other spacers 171 are arranged around the center of the upper surface of the support 150. The ceramic piece may be made of one of the materials described as materials of the electrostatic chuck layer 160. For example, a material identical with the material of the ceramic plate 161 of the electrostatic chuck layer 160 may be used. The height of the spacers 171 and the junction layer 172 (the distance between the electrostatic chuck layer 160 and the support 150) is, for example, 0.01˜0.1 mm. A process of bonding the electrostatic chuck layer 160 on the support 150 is performed in such a way as to coat a thermosetting resin on the support 150, embed the spacers 171 in the junction layer 172, place and press the ceramic plate, and harden the adhesive resin by the application of heat. Thereafter, the ceramic plate 161 is made flat by polishing or grinding the surface thereof.

The junction layer 172 may be made of a mixture obtained by mixing a silicone-based adhesive resin or an acrylic-based adhesive resin with ceramic powder that is a filler material. The materials of the spacers 171 and the junction layer 172 are selected so that relative dielectric constants thereof are equivalent to each other. In this case, the equivalence imports that, if it is assumed that the relative dielectric constant of the spacers 171 is ε1 and the relative dielectric constant of the junction layer 172 is ε2, a relationship of 0.90ε2≦ε1≦1.10ε2 is fulfilled. In view of the object of the present invention, ε1=ε2 is ideal. However, in practice, the relative dielectric constants are made equivalent by adjusting the mixing ratio of the filler materials, so that there may happen to result in a difference of 10%.

As the ceramic powder used for the filler material, a material identical to the material of the ceramic piece making up the spacer 171 may be used, but a different material can be used.

For instance, by mixing a ceramic powder having a relative dielectric constant greater than that of the spacer 171 with an adhesive resin having a relative dielectric constant lower than that of the spacer 171, it is possible to make the relative dielectric constant equivalent with that of the spacer 171. Furthermore, since even ceramics of the same kind, for example, alumina, can have different relative dielectric constants among themselves, alumina having a relatively greater relative dielectric constant may be used as the ceramic powder (filler material) and alumina having a relatively smaller relative dielectric constant may be used as the spacer 171 in the case where ceramic powder having a relative dielectric constant higher than that of the spacer 171 is employed.

The material of the spacer 171 is not limited to the ceramic piece. However, a ceramic piece having a relative dielectric constant equal to or greater than, e.g., 9.0 may be used preferably to enhance the efficiency of the high frequency power, that is, to increase the etching rate considerably.

A DC power supply unit 164 is connected to the chuck electrode 162 of the electrostatic chuck layer 160 through a switch 163. By the application of DC voltage to the chuck electrode 162, the wafer W is adsorbed to the electrostatic chuck layer 162 by, e.g., an electrostatic attractive force generated on the portion of the ceramic plate 161 above the chuck electrode 162. A focus ring 165 and a cover ring 166 made of, e.g., quartz are placed around the electrostatic chuck layer 160 to surround the wafer W that is adsorbed to the electrostatic chuck layer 160.

A high frequency power supply unit 152 for applying a bias voltage having a frequency of, for example, 2 MHz through a high pass filter 151 is connected to the support 150. An inlet path 153 and an outlet path 154 are connected to the support 150, and a temperature control fluid path 155 of temperature control means, which passes a temperature control medium at a temperature of 120° C. therethrough, is formed in the support 150. The temperature control means functions to control the temperature of the wafer W to remain at a set temperature by absorbing heat when the heat is transferred from the plasma to the wafer W. The susceptor 140 is adapted to be selectively lowered and elevated by an elevation mechanism that is installed below the processing vessel 120, and elevation pins (not shown) is provided in the susceptor 140 to transfer and receive the wafer W by using a transport arm. Reference numeral 157 designates a bellows that is used to prevent the plasma from entering the area below the susceptor 140.

The operation of the above-described etching apparatus is described below. After the gate valve 123a is opened, the wafer W, the surface of which is provided with a mask pattern containing a resist film, is carried into the processing vessel 120 from a load lock chamber and mounted on the electrostatic chuck layer 160 of the susceptor 140, and then the gate valve 123a is closed to make the processing vessel 120 airtight. While the gas is exhausted from the processing vessel 120 by a vacuum pump 122, a predetermined amount of a process gas, for example, etching gas including halogenated carbon gas, such as C₄F₆ and C₂F₆, oxygen gas and argon gas, is introduced and uniformly sprayed on the surface of the wafer W through the gas diffusion holes 132, thus maintaining the processing vessel 120 at a vacuum level of several ten mTorr. Further, the etching gas supplied to the processing vessel 120 flows along the surface of the wafer W in a radially outward direction and is uniformly exhausted from the surroundings of the susceptor 140.

Thereafter, a high frequency voltage of, for example, 60 MHz, is applied to the upper electrode 130 from the high frequency power supply unit 134 at, e.g., 1800 W, and after a time interval shorter than 1 minute, a bias voltage of, for example, 2 MHz, is applied to the susceptor 140 from the high frequency power supply unit 152 at, for example, 1850˜2250 W. The high frequency voltage from the high frequency power supply unit 134 reaches the wafer W, passes through the electrostatic chuck layer 160, reaches the support 150 through the spacer 171 or junction layer 172 and flows into the earth through the high pass filter 151. Further, the high frequency voltage from the bias high frequency power supply unit 152 reaches the electrostatic chuck layer 160 from the support 150 through the spacer 171 or junction layer 172 and then reaches the wafer W. As a result, the etching gas, which is the process gas, is converted into a plasma by the high frequency voltage supplied from the high frequency power supply unit 134, the active species of the plasma is vertically incident on the surface of the wafer W to which the high frequency bias has been applied, and, for example, a silicon oxide film or resist film is etched at a predetermined selection ratio.

FIG. 12 shows an equivalent circuit with respect to a high frequency path Pa in the projection region of the spacer 171 (an upper and a lower region including the spacers 171) and a high frequency path Pb in the projection region having a size equal to that of the projection region of the spacers 171. In FIG. 12, if it is assumed that reference character C1 designates the capacitance of the spacers 171, reference character C2 designates the capacitance of the junction layer 172 and reference character C3 designates the capacitance of the electrostatic chuck layer 160, the total capacitance of the electrostatic chuck layer 160 and the spacers 171 in the path Pa are expressed by Equation 1,

$$\begin{matrix}Ca = C1 \cdot C3 / ( C1 + C3 ) \\ = ( ɛ 0 \cdot ɛ 1 / d ) \cdot ( ɛ 0 \cdot ɛ 3 / d3 ) \cdot S / \{ ( ɛ 0 \cdot ɛ 1 / d ) + ( ɛ 0 \cdot ɛ 3 / d3 ) \}\end{matrix} \qquad ( 1 )$$

The total capacitance of the electrostatic chuck layer 160 and the junction layer 172 in the path Pb are expressed by Equation 2,

$$\begin{matrix}Cb = C2 \cdot C3 / ( C2 + C3 ) \\ = ( ɛ 0 \cdot ɛ 2 / d ) \cdot ( ɛ 0 \cdot ɛ 3 / d3 ) \cdot S / \{ ( ɛ 0 \cdot ɛ 2 / d ) + ( ɛ 0 \cdot ɛ 3 / d3 ) \}\end{matrix} \qquad ( 2 )$$

In Equations 1 and 2, ε0 is the relative dielectric constant of a vacuum, ε1 is the relative dielectric constant of the spacer 71, ε2 is the relative dielectric constant of the junction layer 172, ε3 is the relative dielectric constant of the electrostatic chuck layer 160, d is the thickness of the spacer 171 (thickness of the junction layer 172), d3 is the thickness of the electrostatic chuck layer, and S is the area of the longitudinal section of the spacer 171.

The impedance of the frequency path Pa and the impedance of the frequency path Pb are given as 1/ω·Ca and 1/ω·Cb, respectively. When the relative dielectric constant ε1 of the spacer 171 and the relative dielectric constant ε2 of the junction layer 172 are different from each other, the magnitudes of the high frequency powers supplied from the high frequency power supply unit 134 become different by the amount corresponding to the reciprocals of the values of Equations 1 and 2 between both paths Pa and Pb, so that the states of the plasma become different. When the relative dielectric constant ε1 of the spacer 171 is made equal to the relative dielectric constant ε2 of the junction layer 172 (the values of the relative dielectric constants are the same), the magnitudes of the high frequency powers become substantially equal, so that the states of the plasma become same. Furthermore, the same arguments hold with the bias voltage supplied from the high frequency power supply unit 152. That is, the ions in the plasma are attracted to the surface of the wafer W by applying bias voltage having a frequency considerably lower than that of the frequency for the generation of plasma, so that ions are vertically incident on the surface of the wafer W. In this case, the collision energies of ions are accumulated between both paths Pa and Pb, so that the intra-surface uniformity of etching is improved.

Accordingly, in accordance with the above-described embodiment, on the surface of the wafer W, the etching rate (etching speed) in the region corresponding to the projection region of the spacer 171 is equal to the etching rate (etching speed) in the region corresponding to the projection region of the junction layer 172. In practice, the parameters, including the flow rate and pressure of gas, are adjusted so that the etching rate of the central portion of the wafer W is made equal to the etching rate of the peripheral portion of the wafer W. Even in this case, when the efficiency of the high frequency power in one region is equal to the efficiency of the high frequency power in the other region, the high inter-surface uniformity of the etching rate can be assured by the adjustment of parameters, so that the above technique is useful to cope with the thinning of devices and the miniaturization of patterns.

The spacers 171, as shown in FIG. 13, may be configured in such a way that a circular spacer 171 is placed at the center of the support 150 and a ring-shaped spacer 171 is placed around the circular spacer 171 to surround the circular spacer 171, instead of being configured in such a way that a plurality of circular spacers 171 is arranged around a circular spacer 171 as described above.

The plasma processing in accordance with the present invention is not limited to etching processing, but may also be a coating processing or an ashing processing. The apparatus in accordance with the present invention is not limited to the parallel-flat plate type plasma processing apparatus described in conjunction with the above-described embodiment, but may include a device for introducing microwaves into a processing vessel via an antenna and generating a plasma and applying a high frequency bias to a susceptor, or a device for generating a plasma by using electronic cyclotron resonance and applying a high frequency bias to a susceptor.

To examine the effects of the present invention, the electrostatic chuck layer formed by embedding the chuck electrode in the alumina plate was bonded to the surface of the support made of alumina by using the silicone-based adhesive resin, with the spacers formed of aluminum pieces being interposed therebetween in accordance with the layout shown in FIG. 11. The adhesive resin was mixed with alumina powder that was a filler material, and the relative dielectric constant of the mixture was made equivalent to those of the junction layer and the spacers. The relative dielectric constant of the spacer was set to 9.5 and the relative dielectric constant of the junction layer was set to 9.0. The wafer W having the silicon oxide film was mounted on the susceptor constructed as described above, and etching rates were measured under the process conditions described in the above embodiment. In this measurement, it was found out that the intra-surface of an etching rate was desirable.

The third embodiment may be combined with the second embodiment. That is, in connection with the construction of FIG. 10, the coating member 71 in accordance with the second embodiment may be employed to make a tight contact with the side circumferential surface of the junction layer 172.

(Fourth Embodiment)

A processing apparatus in accordance with a fourth embodiment of the present invention is described. FIG. 14 is a longitudinal section showing an entire configuration of a plasma etching apparatus that is a processing apparatus in accordance with the present embodiment of the present invention.

In FIG. 14, reference numeral 210 designates a vacuum chamber making up a part of the processing apparatus, which is made of a conductive material, such as aluminum, to form an airtight structure and is electrically grounded. A roughly cylindrical deposition shield 212 is fitted onto the inside circumferential surface of the vacuum chamber 210 to prevent the inside circumferential surface of the vacuum chamber 210 from being damaged by the plasma. In the vacuum chamber 210, a gas showerhead 214 also functioning as an upper electrode and a susceptor 216 also functioning as a lower electrode are arranged opposite to face each other. A vacuum exhaust line 218 is formed in the bottom portion of the vacuum chamber 210 to communicate with vacuum exhaust means (not shown) including a turbo molecular pump or a dry pump.

An opening 220 is formed through the sidewall of the vacuum chamber 210 to carry in and out a wafer W that is a substrate to be processed, and can be selectively opened and closed by a shutter 222 that can be selectively elevated and lowered by an air cylinder. The gas showerhead 214 includes a high frequency plate 214a, a cooling plate 214b, and an electrode plate 214c. A high frequency power supply 226 is connected to the high frequency plate 214a through a matching unit 224, and a high frequency power having a frequency of, for example, 13.56˜100 MHz is applied to the high frequency plate 214a.

A medium circulation path 228 is provided in the high frequency plate 214a, and the temperatures of the cooling plate 214b and the electrode plate 214c coming into contact with the high frequency plate 214a can be set to desired temperatures by activating temperature control means (not shown), respectively. The temperature control means includes an inlet line 230 for circulating coolant through the medium circulation path 228. The coolant, the temperature of which has been adjusted to a predetermined temperature, is supplied to the medium circulation path 228 through the inlet line 230, and experiences a heat exchange. Thereafter, the coolant is exhausted to the outside of the apparatus through an outlet path (not shown). Furthermore, the medium circulation path 228 may be installed in the cooling plate 214b. With this, the electrode plate 214c can be actively cooled, which is preferable.

Gas supply means 232 is connected to the gas shower head 214, and the process gas, which has passed through a gas supply line 234 connected to a gas source (not shown) and the flow rate or pressure of which has been controlled, is supplied to the vacuum chamber 210. A plurality of gas supply paths and gas holes 236 is formed through the cooling plate 214b and the electrode plate 214c to correspond to the size of the wafer W placed on the susceptor 216, and the gas supply paths and the gas holes 236 are constructed to uniformly supply the process gas from the gas supply means 232 to the surface of the wafer W.

The susceptor 216 is installed below the gas shower head 214 to be spaced apart from the gas shower head 214 by a distance of approximately 5˜150 mm. The susceptor 216 includes an electrode body 244 made of, e.g., anodic oxidation-treated aluminum, and an insulator 238 used to insulate the electrode body 244 from the vacuum chamber 210. The electrode body 244 is provided with an electrostatic adsorption mechanism for adsorbing and holding the wafer W, and is connected to the high frequency power supply 242 via the matching unit 240. A high frequency power having a frequency of, for example, 800 kHz˜3.2 MHz is applied to the electrode body 244 from the high frequency power 242.

An annular focus ring 246 is placed around the electrode body 244. The focus ring 246 is made of an insulating or conductive material depending on a process, and functions to confine or diffuse ions. An insulator 248, which is entirely made of an insulating material or is formed by coating a conductive material with an insulating film, is placed outside of the focus ring 246.

An exhaust ring 250, which is provided with a plurality of exhaust holes, is placed between the susceptor 216 and the sidewall of the vacuum chamber 210 and below the surface of the susceptor 216 (the mounting surface) to surround the susceptor 216. By the exhaust ring 250, the flow of the exhausted gas is adjusted and the plasma is appropriately confined between the susceptor 216 and the gas showerhead 214. A plurality of elevation pins, for example, three elevation pins, which are elevation members for transferring and receiving a wafer to and from an external transport arm (not shown), are provided in the susceptor 216 to be projected and retracted. These elevation pins are configured to be selectively elevated and lowered by a drive device (not shown).

With reference to FIG. 15 that is a schematic sectional view showing the electrode body 244, the major elements of the present embodiment will now be described.

As shown in FIG. 15, the electrode body 244 includes an electrostatic adsorption unit (electrostatic adsorption device) 254 and a high frequency plate 256. The high frequency power supply 242 is connected to the high frequency plate 256 through a matching unit 240, and a high frequency power having a frequency of 800 kHz˜3.2 MHz is applied to the electrode body 244. In the present embodiment, a medium circulation path 258 is formed in the high frequency plate 256, and a medium, the temperature of which has been controlled, is supplied from medium supply means (not shown) through a supply line 260 to the medium circulation path 258.

The electrostatic adsorption unit 254 provided on the high frequency plate 256 includes a dielectric 254a, an adsorption electrode 254b contained in the dielectric 254a, and a ferromagnetic substance 254c. In the present embodiment, the electrostatic adsorption unit 254 and the ferromagnetic substance 254c are integrated into a single body. The dielectric 254a is made of ceramic or the like that is formed by sintering or thermal spraying and is selected from materials, such as aluminum oxide Al₂O₃ and aluminum nitride AlN. A desired adsorption force may be obtained in such a way as to adjust a volume specific resistance or a relative dielectric constant by adding titanium dioxide TiO₂ and silicon carbide SiC to the material.

The adsorption electrode 254b is placed in the vicinity of the surface of the electrode body 244, and is made of, for example, tungsten in the form of a sheet. The adsorption electrode 254b is constructed to switch between a DC power supply 262 and a ground through a switch SW1. By applying a DC voltage to the adsorption electrode 254b, an electrostatic adsorption force is generated between the dielectric 254a and the wafer W.

The ferromagnetic substance 254c is placed in contact with or in the vicinity of the bottom surface of the adsorption electrode 254b. The material of the ferromagnetic substance 254c is selected to correspond to a process to be performed in the vacuum chamber 210. Specifically, a material having a Curie point at a control temperature is selected. For example, when the wafer W is heated to 110˜120° C., Mn—Zn ferrite or Ni—Zn ferrite is selected.

The ferromagnetic substance 254c is formed at the adsorption electrode 254b or the dielectric 254a by dissolving the ferromagnetic substance in a solvent and using a known coating or thermal spraying method. The ferromagnetic substance may be formed in the shape of a plate by using a sintering method and the plate-shaped ferromagnetic substance may be bonded to the dielectric 254a by using a bonding agent. Otherwise, the ferromagnetic substance may be formed in the form of particles and the ferromagnetic particles may be added to the dielectric 254a. In the case where the dielectric 254a is constructed to be porous, the pores of the dielectric 254a may be filled with the ferromagnetic substance 254c dissolved in a solvent. As described above, the method of producing the ferromagnetic substance 254c is preferably selected based on the material or environment of use of the ferromagnetic substance 254c.

The operation of the plasma etching apparatus constructed as described above is described below.

The wafer W is carried into the vacuum chamber 210 through the opening 220 and the shutter 222 and is mounted on the susceptor 216. Thereafter, the shutter 222 is closed and the vacuum chamber 210 is exhausted to a predetermined vacuum level through the vacuum exhaust line 218 by using vacuum exhaust means. The wafer W is electrostatically adsorbed to the surface of the susceptor 216 by supplying process gas to the vacuum chamber 210 and applying a DC voltage to the adsorption electrode 254b.

Thereafter, a high frequency power having a predetermined frequency is applied from the high frequency power supplies 226 and 242. By this, a high frequency electric field is formed between the gas shower head 214 and the susceptor 216 and the process gas is converted into a plasma, so that etching processing is performed on the wafer W mounted on the susceptor 216. Since the ferromagnetic substance 254c having a Curie point at a control temperature is mounted in the susceptor 216, the ferromagnetic substance 254c generates heat by an eddy current loss caused by dielectric action as the high frequency power is applied to the high frequency plates 214a and 256.

When a high frequency current passes through the inside of the ferromagnetic substance 254c, magnetic force lines (magnetic field) are generated on the surface of the ferromagnetic substance 254c by the high frequency current, and an eddy current is generated to cancel the magnetic force lines. Heat is generated in a portion of the ferromagnetic substance 254c in the vicinity of the surface of the ferromagnetic substance 254c by resistive heat.

The temperature of the ferromagnetic substance 254c is increased by the generation of heat, and the ferromagnetic substance 254c is converted into a paramagnetic substance when the temperature of the ferromagnetic substance 254c exceeds the Curie point, thus remaining at a constant temperature. If necessary, it is possible to control the temperature of the wafer W on the susceptor 216 with high precision by controlling the flow rate or temperature of the coolant circulating through the medium circulation path 258.

The ferromagnetic substance 254c preferably has a thickness slightly greater than double the skin depth. The skin depth is used as a reference for the depth through which a current flows, and is expressed by Equation 3,
Skin depth δ=(2ρ/ωμ)^{1/2} (3)
where ρ is a specific resistance, ω is 2πf (f: frequency) and μ is μ₀(1+χ) (μ₀: transmittance of vacuum, χ: magnetic susceptibility).

As described above, in accordance with the present embodiment, the electrode to which the high frequency power is applied is formed of the ferromagnetic substance 254c, so that the temperature thereof can be controlled by using the Curie point of the material thereof. Accordingly, without the use of the conventional heat mechanism, the heating of the electrode placed in the vacuum chamber 210 can be controlled by using a very simple construction. Since the ferromagnetic 254c accurately stops the generation of heat at a Curie point specific to the material thereof, the temperature of the wafer W can be precisely controlled by determining the amount of heat input.

An embodiment in which the above-described temperature control construction is applied to a gas showerhead functioning as an upper electrode will now be described. FIG. 16 is a schematic sectional view showing a gas shower head 214′ that is applied to the present embodiment. Same as the embodiment of FIG. 15, a ferromagnetic substance having a Curie point is placed in the electrode, that is, the gas shower head 214′, and the gas shower head 214′ is heated.

As shown in FIG. 16, the gas shower head 214′ includes a high frequency plate 214a, a cooling plate 214b and an electrode plate 214c, same as the gas shower head 214 of FIG. 14, and further includes a ferromagnetic substance 264 that is located below the electrode plate 214a and in contact with or in the vicinity of the electrode plate 214c. A hole is formed through the ferromagnetic substance 264 to communicate with a gas supply line and a gas hole 236. Like the embodiment illustrated by using FIG. 15, the ferromagnetic substance 264 may be formed on the bottom surface of the electrode plate 214c in the shape of a film by using a known coating or thermal spraying method. The ferromagnetic substance 264 may be formed in the shape of a plate by using a sintering method and then be bonded to the surface of the electrode plate 214c. Ferromagnetic powder may be employed and be added to the electrode plate 214c. The surface of the ferromagnetic substance 264 is coated with an insulating film, such as ceramic or resin.

When a high frequency power is applied to the high frequency plate 214a, the ferromagnetic substance 264 generates heat until the temperature of the ferromagnetic substance 264 reaches the Curie point. When the temperature of the ferromagnetic substance 264 exceeds the Curie point, the ferromagnetic substance 264 is converted into a paramagnetic substance from which no heat is emitted, so that the ferromagnetic substance 264 is maintained at the temperature of the Curie point. The temperature of the gas shower head 214′ can be controlled at a desired temperature with accuracy by circulating temperature controlled coolant through the medium circulation path 228 while monitoring the temperature of the gas shower head 214′.

Although, in the embodiment illustrated by using FIG. 15, only the apparatus in which the ferromagnetic substance 254c is placed in the electrostatic chuck layer 254 has been described, the high frequency plate 256 to which the high frequency power is applied may be formed of a ferromagnetic substance. Likewise, in the embodiment illustrated by using FIG. 16, the ferromagnetic substance 264 is placed to make a contact with or in the vicinity of the electrode plate 214c, whereas the high frequency plate 214a itself may be made of a ferromagnetic material.

Furthermore, although, in the above-described embodiments, the examples in which the lower electrode for holding the wafer W and the upper electrode corresponding to the lower electrode were horizontally arranged in parallel have been described, the present invention is not limited to this construction but may be applied to a processing apparatus in which two electrodes are vertically arranged and spaced apart from each other.

Furthermore, although, in the above-described embodiment, parallel-flat plate type plasma etching apparatus has been described as an example, the present invention is not limited to this construction. The present invention may be applied to various plasma processing apparatuses, such as magnetron type and inductive coupling type plasma processing apparatuses. Furthermore, the present invention may be applied to an apparatus for performing processing on a glass substrate for a Liquid Crystal Display (LCD).

In accordance with the present embodiment, the electrode having the high frequency plate to which the high frequency power is applied is constructed to have the heating element formed of a ferromagnetic substance, so that the temperature of the heating element can be controlled at the Curie point temperature of the material of the heating element. Accordingly, the heating of the electrode can be controlled by the very simple construction without using the conventional heating mechanism. Furthermore, since the ferromagnetic substance making up the heating element accurately stops the generation of heat at a Curie point specific to the substance, the temperature of an object to be processed can be accurately controlled based on the measurement of the amount of input heat.

### BRIEF DESCRIPTION OF THE DRAWINGS

FIG. 1 is a longitudinal section showing an entire construction of an example of an etching apparatus that is a processing apparatus in accordance with a first embodiment.

FIG. 2 is a sectional view showing a susceptor that is installed in the processing apparatus.

FIG. 3 is a view showing a method of producing a junction layer formed in the susceptor.

FIG. 4 is a view showing a method of producing the susceptor.

FIG. 5 is a graph illustrating an effect in accordance with a first embodiment of the present invention.

FIG. 6 is a view showing a susceptor in accordance with a second embodiment of the present invention.

FIG. 7 is a view showing a method of fitting a coating member into the susceptor.

FIG. 8 is a view showing specific shapes of coating members.

FIG. 9 is a longitudinal section of a plasma processing apparatus in accordance with a third embodiment of the present invention.

FIG. 10 is a schematic diagram showing a susceptor of the plasma processing apparatus.

FIG. 11 is a plan view showing an example of the layout of spacers arranged on a support.

FIG. 12 is a circuit equivalent to paths of a high frequency power ranging from a wafer to a support.

FIG. 13 is a plan view showing another example of the layout of spacers arranged on a support.

FIG. 14 is a longitudinal section showing a plasma etching apparatus in accordance with a fourth embodiment of the present invention.

FIG. 15 is a schematic sectional view showing an electrode body making up the susceptor of the plasma etching apparatus shown in FIG. 14.

FIG. 16 is a schematic sectional view showing a gas showerhead of the plasma etching apparatus in accordance with the fourth embodiment of the present invention.

FIG. 17 is a longitudinal section view showing a conventional processing apparatus.

FIG. 18 is a longitudinal section view showing the susceptor of the conventional processing apparatus.

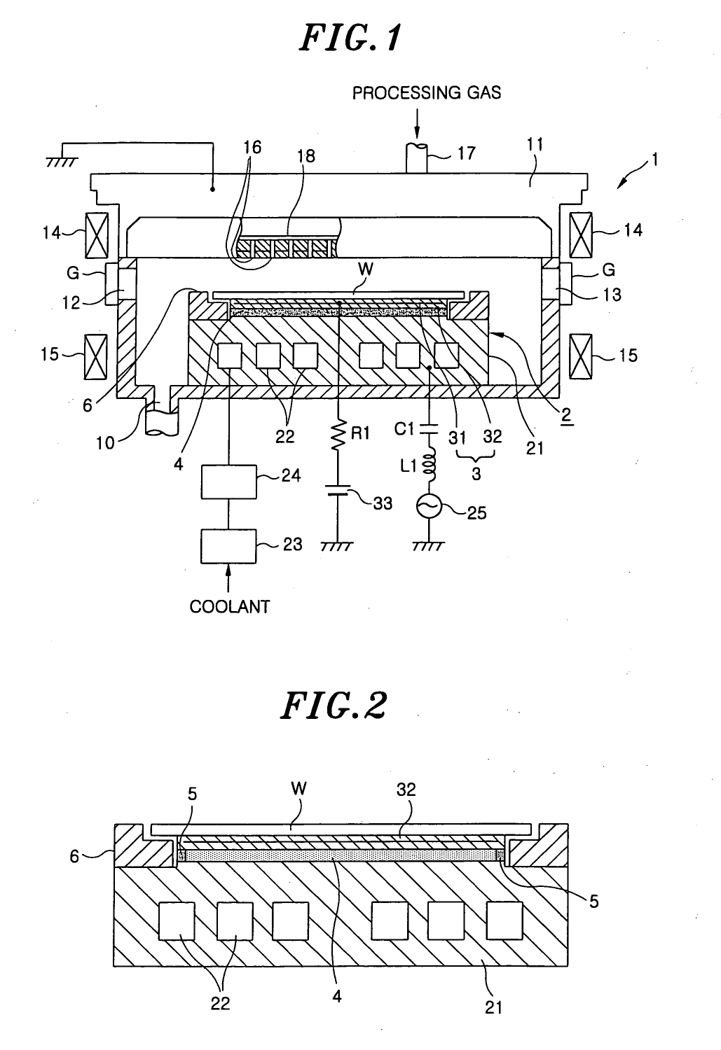

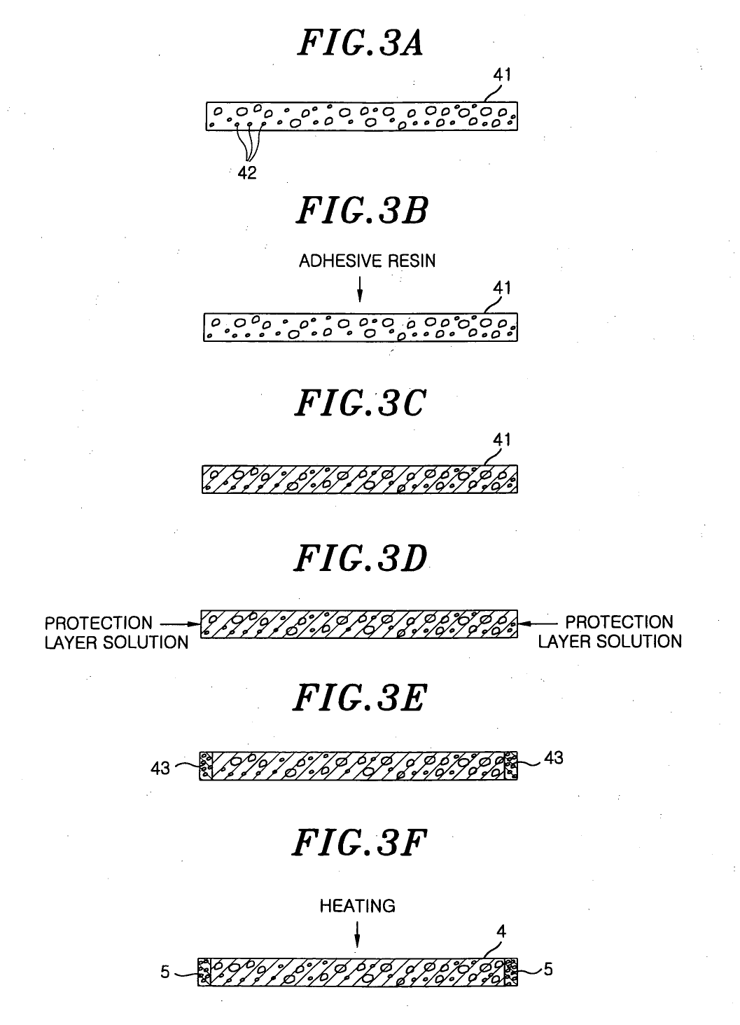

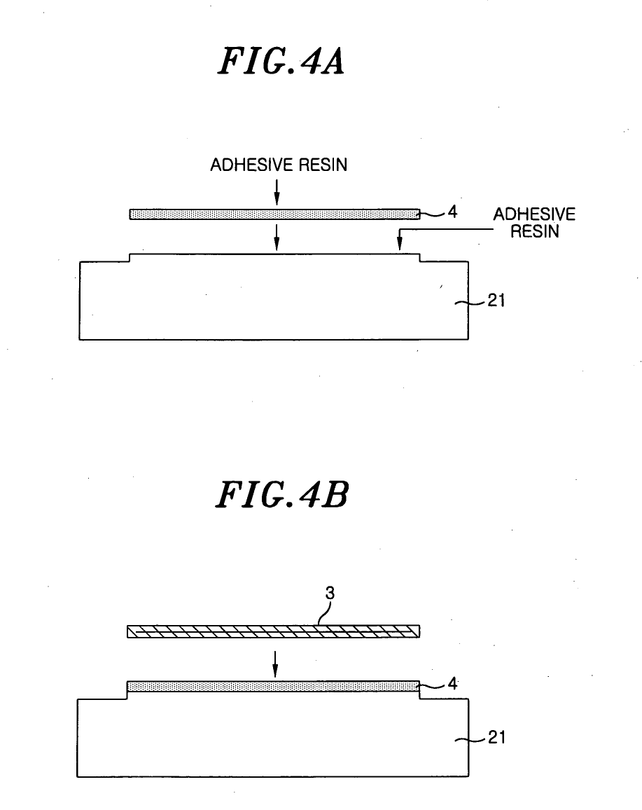

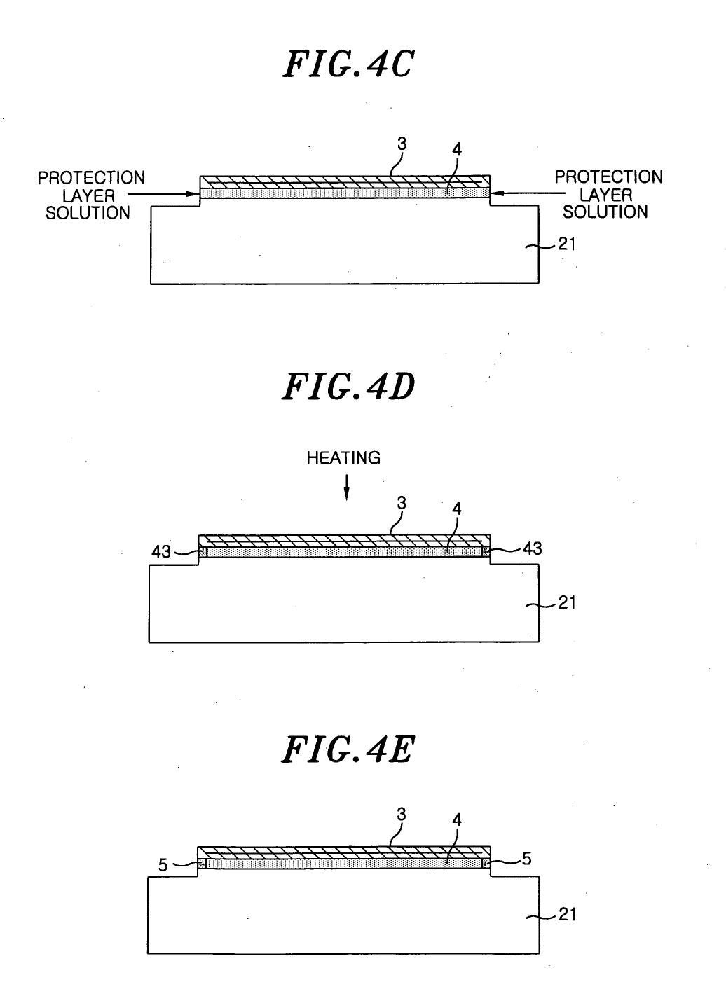

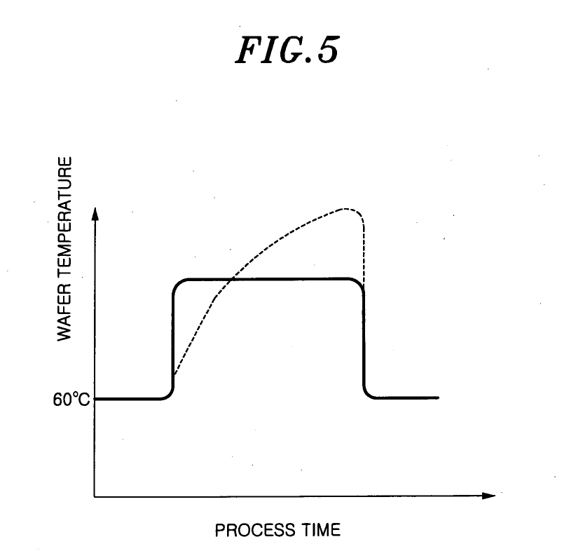

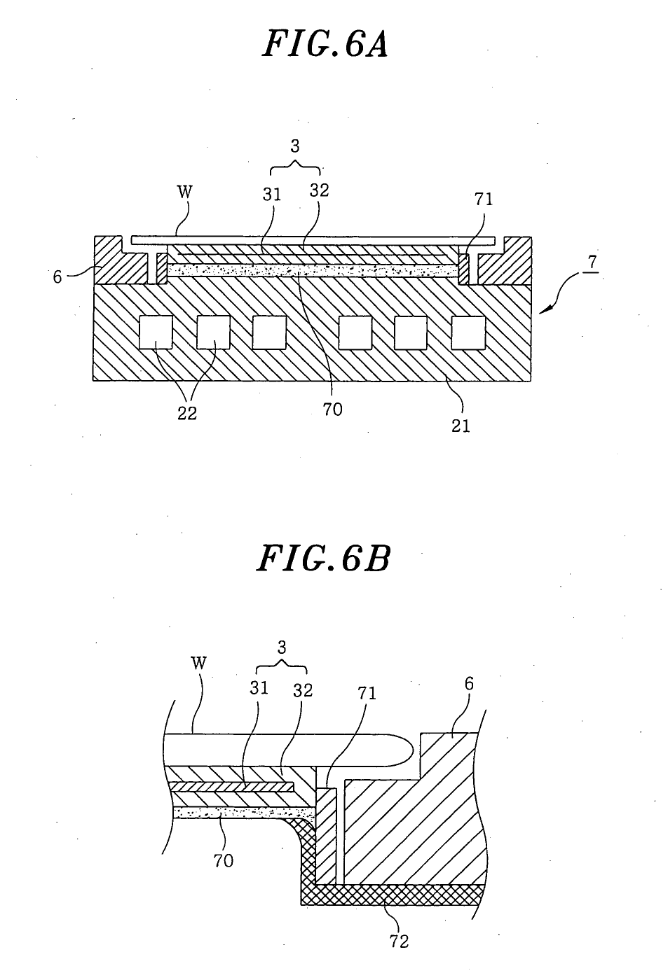

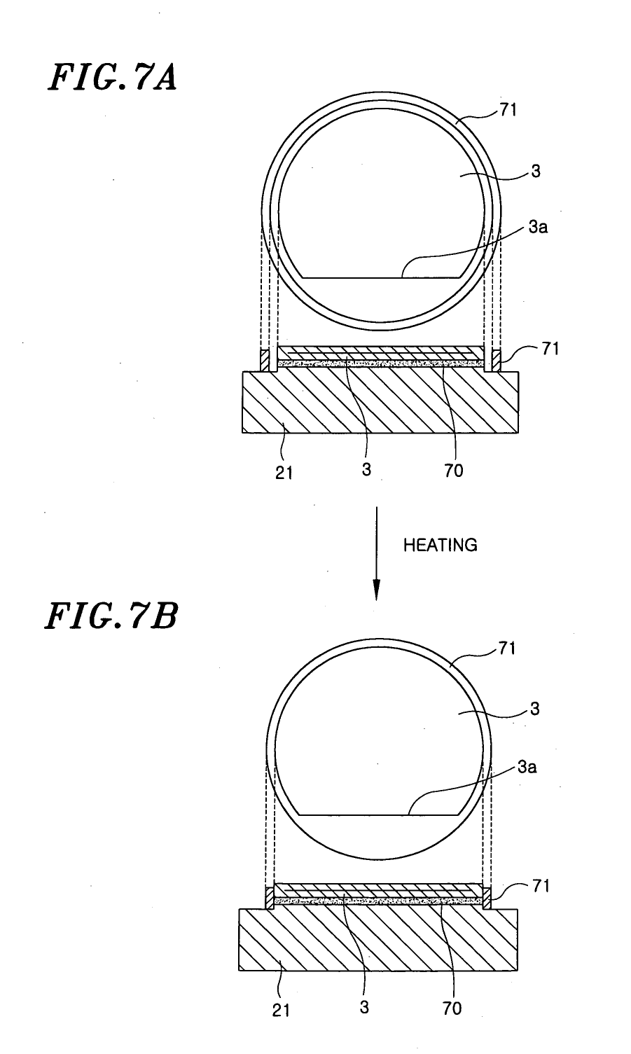

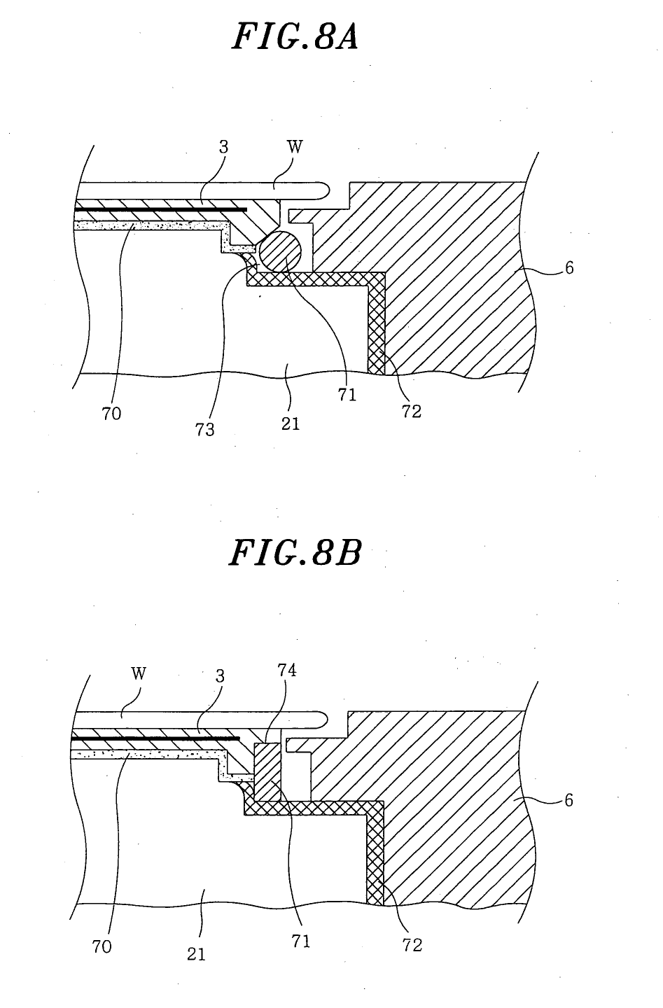

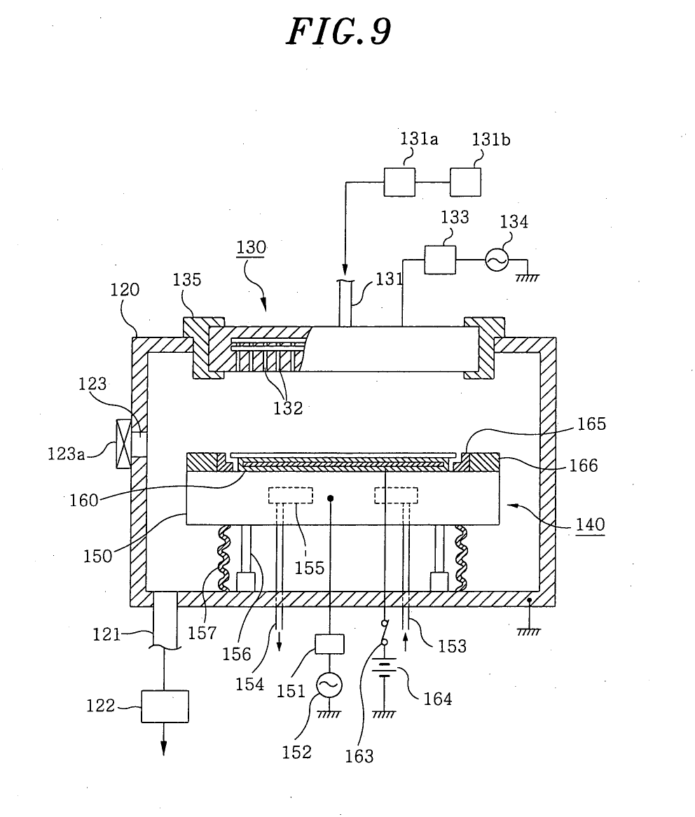

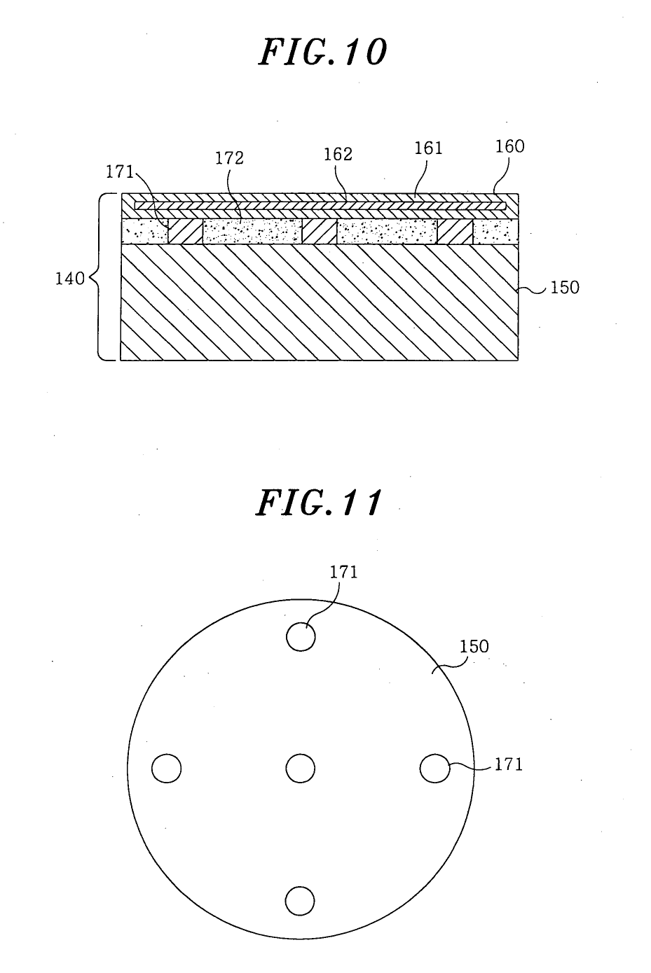

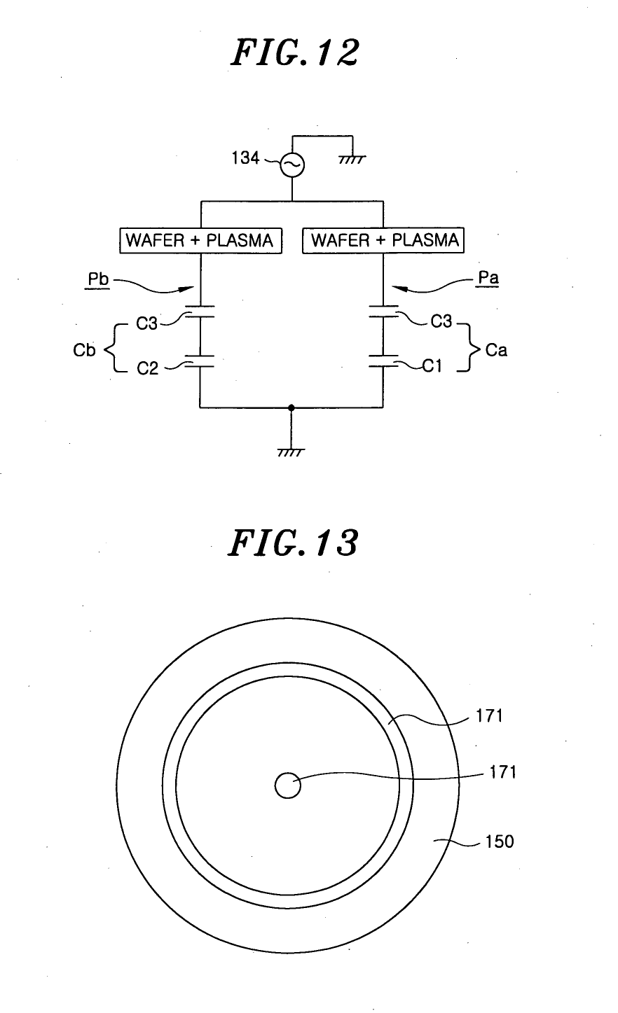

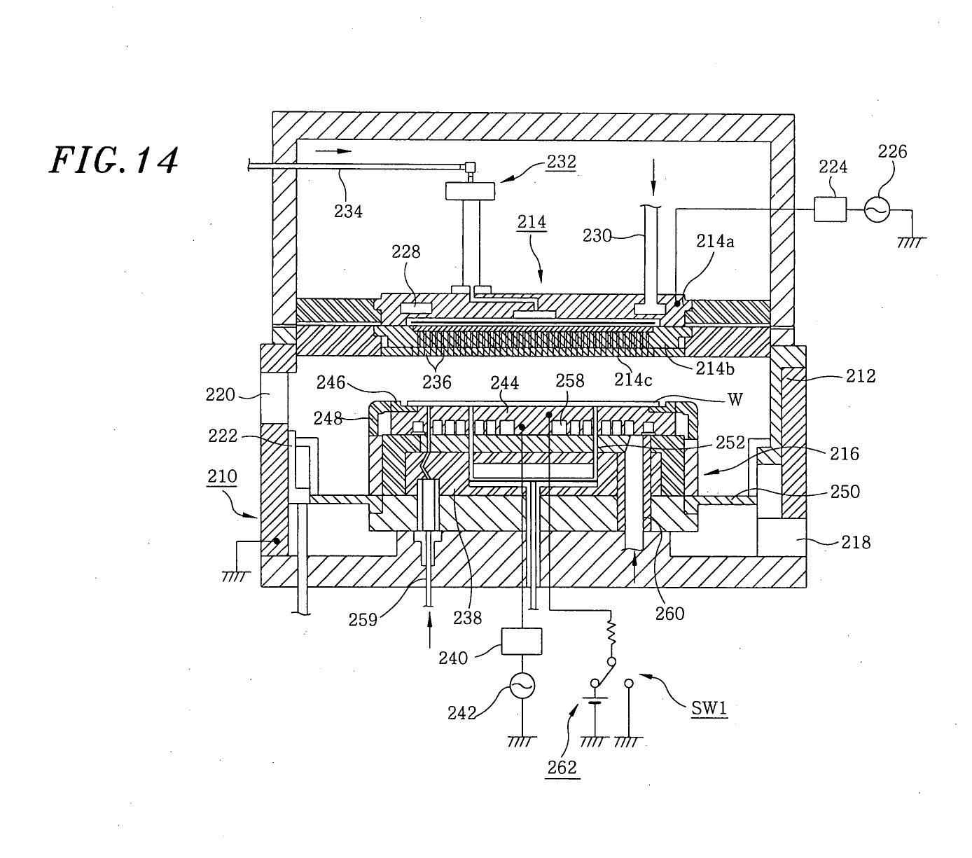

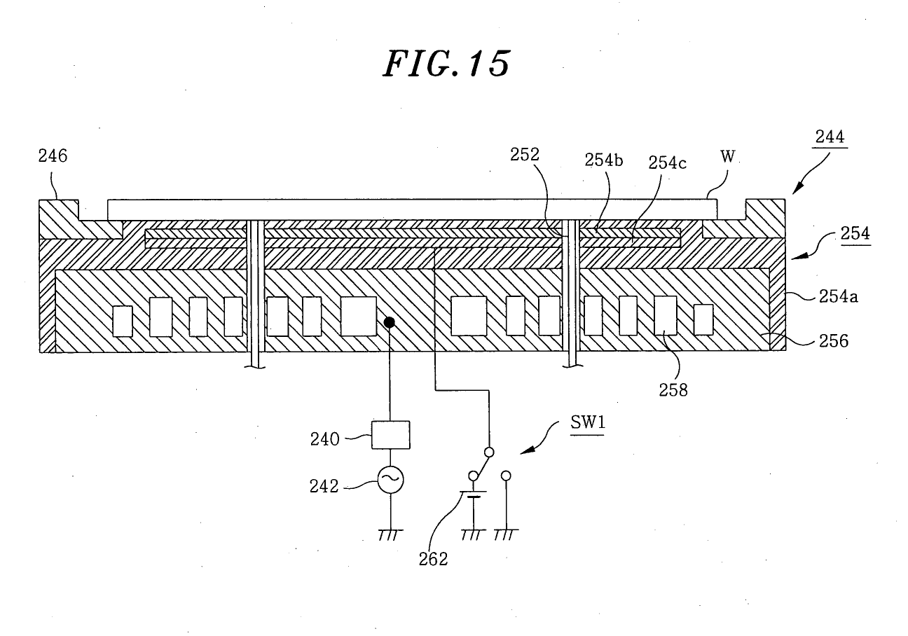

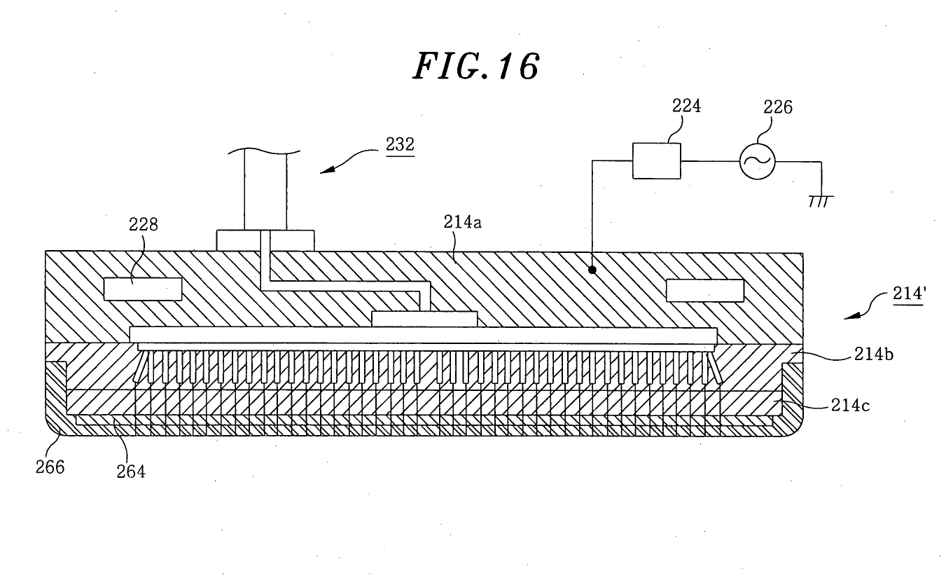

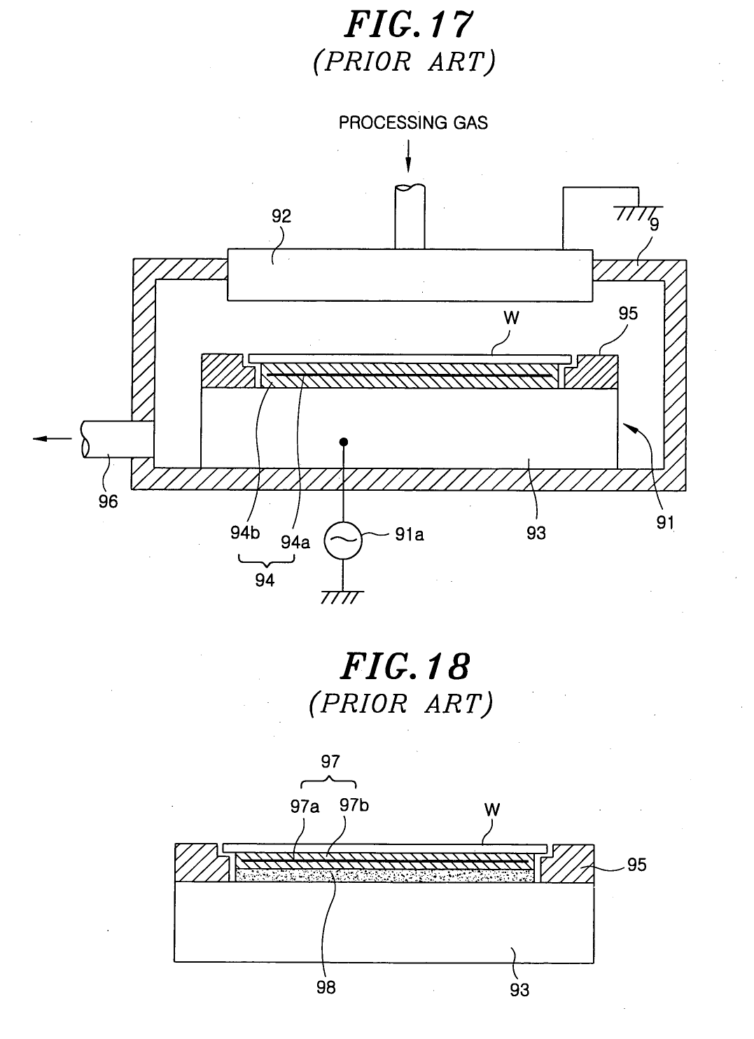

### DESCRIPTION OF REFERENCE NUMERALS

W: wafer
1: vacuum chamber
11: upper electrode
2: susceptor
25: high frequency power supply
3: electrostatic chuck layer
31: chuck electrode
4: junction layer
5: protection layer
6: ring member
7: susceptor
70: junction layer
71: coating member
72: thermally sprayed coating
73: space
74: groove

1. A processing apparatus comprising:
a processing vessel for performing a predetermined processing on a substrate;
an electrostatic chuck layer for holding the substrate by using an electrostatic adsorption force generated by a voltage applied, the electrostatic chuck layer being placed in the processing vessel and formed by coating a chuck electrode with an insulating layer;
a support for supporting the electrostatic chuck layer; and
a junction layer for bonding the support and the electrostatic chuck layer together, the junction layer being interposed between the support and the electrostatic chuck layer and formed by impregnating a porous ceramic with an adhesive resin.

2. A processing apparatus comprising:
a processing vessel for performing a plasma processing on a substrate;
an electrostatic chuck layer for holding the substrate by using an electrostatic adsorption force generated by a voltage applied, the electrostatic chuck layer being placed in the processing vessel and formed by coating a chuck electrode with an insulating layer;
a support for supporting the electrostatic chuck layer;
a junction layer for bonding the support and the electrostatic chuck layer together, the junction layer being interposed between the support and the electrostatic chuck layer and formed by impregnating a porous ceramic with an adhesive resin; and
a protection layer for protecting the junction layer against active species generated by plasma, the protection layer being formed around a side circumferential surface of the junction layer.

3. The processing apparatus of claim 1, wherein the porous ceramic is one of alumina, aluminum nitride and silicon carbide.

4. The processing apparatus of claim 2, wherein the protection layer is formed by impregnating a protection layer solution, which is formed by dissolving protection layer components in a solvent, into the side circumferential surface of the junction layer to a predetermined depth, and eliminating the solvent from the protection layer solution through heating.

5. The processing apparatus of claim 4, wherein a component of the protection layer is an inorganic material that is not etched by the active species generated by the plasma.

6. The processing apparatus of claim 5, wherein the inorganic material is silica.

7. The processing apparatus of claim 1, wherein the processing apparatus performs a plasma processing on the substrate, and the support is provided with cooling means for controlling a temperature of the support at a predetermined temperature.

8. The processing apparatus of claim 1, further comprising a process gas supply unit for supplying a process gas into the processing vessel and a high frequency power supply for applying a plasma generation high frequency power to the support;
wherein the plasma is generated in the processing vessel and the process gas is activated by the plasma.

9. The processing apparatus of claim 1, wherein the electrostatic chuck layer is formed of a sintered body that is formed by coating the chuck electrode with the insulating layer.

10. A processing apparatus comprising:
a processing vessel for performing a plasma processing on a substrate;
an electrostatic chuck layer for holding the substrate by using an electrostatic adsorption force generated by a voltage applied, the electrostatic chuck layer being placed in the processing vessel and formed by coating a chuck electrode with an insulating layer;
a support for supporting the electrostatic chuck layer, the support being made of a material different from that of the electrostatic layer;
a junction layer for bonding the support and the electrostatic chuck layer together, the junction layer being interposed between the support and the electrostatic chuck layer; and
a coating member for protecting the junction layer against active species generated by a plasma, the coating member being formed to coat a side circumferential surface of the junction layer.

11. The processing apparatus of claim 10, wherein the coating member is a heat shrink tube.

12. The processing apparatus of claim 11, wherein the heat shrink tube is made of a fluoric resin.

13. The processing apparatus of claim 12, wherein the fluoric resin is one of tetrafluoroethylene perfluoroalkoxy vinyl ether (PFA), tetrafluoroethylene-perfluorpropylen copolymer (FEP) and polytetrafluoroethylene (PTFE).

14. The processing apparatus of claim 10, wherein the coating member is one of rubber and elastomer.

15. The processing apparatus of claim 14, wherein a depression is formed by projecting the electrostatic chuck layer and the support to an outside of the junction layer, and the coating member is fitted into the depression so that the coating member pushes surfaces of the electrostatic chuck layer and the support by a restoring force within the depression.

16. The processing apparatus of claim 11, wherein the coating member is coated with fluorine.

17. The processing apparatus of claim 10, wherein a high frequency power is supplied to the support to generate a plasma, and a spacer having a relative dielectric constant equal to that of the junction layer is interposed between the electrostatic chuck layer and the support.

18. The processing apparatus of claim 17, wherein the spacer is formed of a ceramic piece, and the junction layer is formed by mixing an adhesive resin with ceramic powder that is a filler material.

19. The processing apparatus of claim 10, wherein the junction layer is made of one of a silicone-based adhesive resin and an acrylic-based adhesive resin.
